(19) United States
(12) Patent Application Publication
(10) Pub. No.: US 2006/0275952 A1
(43) Pub. Date: Dec. 7, 2006

(54) Method for making electronic devices

(75) Inventors: Arun Virupaksha Gowda, Niskayuna, NY (US); Sandeep Shrikant Tonapi, Niskayuna, NY (US); Ryan Christopher Mills, Rexford, NY (US); David Richard Esler, Mayfield, NY (US); Stephen Andrew Latham, Clifton Park, NY (US); John Robert Campbell, Clifton Park, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company

(21) Appl. No.: 11/146,838

(22) Filed: Jun. 7, 2005

(51) Int. Cl. H01L 21/00

(52) U.S. Cl. 438/122

(57) ABSTRACT

Disclosed are methods for forming an electronic device that comprises a material that functions as an underfill material as well as a thermal interface material simultaneously. The electronic assembly comprising a heat dissipating element, a semiconductor chip, a substrate and a thermally conductive material is also given here, wherein the thermally conductive material serves as an underfill material as well as a thermal interface material simultaneously.

### STATEMENT REGARDING FEDERALLY SPONSORED RESEARCH & DEVELOPMENT

This invention was made with Government support under contract number 70NANB2H3034 awarded by National Institute of Standards and Technology. The Government has certain rights in the invention.

### BACKGROUND

The invention relates generally to a method of forming an electronic device which comprises a material which interfaces between a heat dissipating element and a semiconductor chip, while also at least partially filling the interlayer zone between a semiconductor chip and a substrate, said material serving the purpose of a thermal interface material and an underfill material in these applications.

In typical electronic devices and electronic assemblies, a semiconductor chip is attached to a substrate via at least one electrical interconnect. Due to the coefficient of thermal expansion (CTE) mismatch between the semiconductor chip and the substrate, the electrical interconnects are subjected to shear stresses during operation which cause them to fail prematurely. Such failures may be avoided by the effective reduction of stress on the electrical interconnect. This is achieved by the coupling of the semiconductor chip and the substrate using an underfill material. Also, to remove heat that is generated during operation, a heat dissipating element may be linked to the semiconductor chip via a thermal interface material.

The underfill material and the thermal interface material are typically applied and processed in two different stages during the electronic device preparation. In a typical device preparation method, the underfill material is first dispensed along the edge or edges of the semiconductor chip. The underfill material flows underneath the semiconductor chip and fills the interlayer zone (gap) between the semiconductor chip and the substrate. The underfill material is then cured. In an independent step, the thermal interface material is dispensed onto the backside of the semiconductor chip. A heat dissipating element is then placed in contact with the thermal interface material on the semiconductor chip, and the thermal interface material is then cured. Typically, the heat dissipating element is structured such that it contacts the surface of the substrate and is affixed to the substrate with a sealant. Known methods require a dispensing and curing step for each material employed, the underfill material and the thermal interface material. This adds additional curing cycles and time to the preparation of the electronic device. Thus, there is a need in the art to develop methods that simplify the preparation of electronic devices.

### BRIEF DESCRIPTION

In one aspect, the invention provides a method of forming an electronic device, said method comprising the steps of:

(A) providing a substrate linked to a semiconductor chip via at least one electrical interconnect, said substrate, said semiconductor chip and said at least one electrical interconnect defining an interlayer zone;

(B) coating a predetermined portion of a heat dissipating element with a curable flowable thermally conductive material to provide a coated heat dissipating element;

(C) joining the coated heat dissipating element with the semiconductor chip to provide an electrical structure comprising a heat dissipating element, a substrate linked to a semiconductor chip via at least one electrical interconnect; said electrical structure comprising an interlayer zone defined by the substrate, the electrical interconnect, and the semiconductor chip; and causing the curable flowable thermally conductive material to fill at least a portion of said interlayer zone and subsequently curing the curable flowable thermally conductive material.

In another aspect, the invention provides a method of forming an electronic device, said method comprising the steps of:

(A) providing a substrate linked to a semiconductor chip via at least one electrical interconnect, said substrate and said semiconductor chip and said at least one electrical interconnect defining an interlayer zone;

(B) coating a predetermined portion of a heat dissipating element with a curable flowable thermally conductive material to provide a coated heat dissipating element;

(C) joining the coated heat dissipating element with the semiconductor chip to provide an electrical structure comprising a heat dissipating element, a substrate linked to a semiconductor chip via at least one electrical interconnect; said electrical structure comprising an interlayer zone defined by the substrate, the electrical interconnect, and the semiconductor chip; and causing the curable flowable thermally conductive material to fill at least a portion of said interlayer zone and subsequently curing the curable flowable thermally conductive material;

said electronic device being substantially free of sealant material other than the cured thermally conductive material joining the heat dissipating element to the substrate.

In another aspect, the invention provides a method of forming an electronic device, said method comprising the steps of:

(A) providing a substrate linked to a semiconductor chip via at least one electrical interconnect, said substrate and said semiconductor chip and said at least one electrical interconnect defining an interlayer zone;

(B) filling at least a portion of said interlayer zone with a curable flowable thermally conductive material;

(C) coating a predetermined portion of the semiconductor chip;

(D) joining a structure formed by steps (A)-(C) to a heat dissipating element; and

(E) curing the curable flowable thermally conductive material;

said electronic device being substantially free of sealant material other than the cured thermally conductive material joining the heat dissipating element to the substrate.

In yet another aspect, the invention provides an electronic device comprising:

(A) a substrate;

(B) a semiconductor chip that is linked to the substrate via at least one electrical interconnect, said substrate and said semiconductor chip and said at least one electrical interconnect defining an interlayer zone;

(C) a heat dissipating element; and

(D) a cured thermally conductive material that forms a thermal interface layer between the heat dissipating element and the semiconductor chip, said cured thermally conductive material also occupying at least a portion of said interlayer zone, said electronic device being substantially free of sealant material other than the cured thermally conductive material joining the heat dissipating element to the substrate.

### DRAWINGS

These and other features, aspects, and advantages of the present invention will become better understood when the following detailed description is read with reference to the accompanying drawings in which like characters represent like parts throughout the drawings, wherein:

FIG. 1 illustrates an exemplary arrangement of a flip-chip assembly prior to its being joined to a heat dissipating element coated with a curable flowable thermally conductive material;

FIG. 2 illustrates a first electrical structure 28 that is formed by joining a first assembly 10 shown in FIG. 1 joined to a second assembly 22;

FIG. 3 illustrates an exemplary electronic device comprising flip-chip assembly shown in FIG. 1 after the formation of an electrical structure and curing;

FIG. 4 illustrates an exemplary arrangement of a flip-chip assembly prior to the application of a curable flowable thermally conductive material attached to a heat dissipating element;

FIG. 5 illustrates the same flip-chip assembly shown in FIG. 4 after the formation of an electrical structure;

FIG. 6 illustrates an electronic device 40 comprising the same flip-chip assembly shown in FIG. 4 after the electrical structure shown in FIG. 5 is subjected to curing conditions;

FIG. 7 illustrates an exemplary arrangement of a flip-chip assembly wherein a curable flowable thermally conductive material is applied through a capillary underfill technique to fill the interlayer zone between the substrate and the semiconductor chip;

FIG. 8 illustrates the same flip-chip assembly shown in FIG. 7 wherein the semiconductor chip is coated with the same curable flowable thermally conductive material 26 present in the interlayer zone shown in FIG. 7;

FIG. 9 illustrates an electrical structure 38 comprising the same flip-chip assembly shown in FIG. 8 and a heat dissipating element 24 in contact with the curable flowable thermally conductive material 26 that coats and underfills the semiconductor chip;

FIG. 10 illustrates an electronic device 50 derived from the electrical structure shown in FIG. 9 after the electrical structure has been subjected to curing conditions;

FIG. 11 illustrates an exemplary arrangement of a Wafer Level Chip Scale Packaging (WLCSP) assembly 54 prior to being joined with an assembly 22 comprising a curable flowable thermally conductive material 26 attached to a heat dissipating element 24;

FIG. 12 illustrates an exemplary arrangement of the same WLCSP assembly 54 shown in FIG. 11 after the formation of an electrical structure 58 and curing.

### DETAILED DESCRIPTION

The invention may be understood more readily by reference to the following detailed description of preferred embodiments of the invention and the examples included therein. In the following specification and the claims which follow, reference will be made to a number of terms which shall be defined to have the following meanings:

The singular forms “a”, “an” and “the” include plural referents unless the context clearly dictates otherwise.

“Optional” or “optionally” means that the subsequently described event or circumstance may or may not occur, and that the description includes instances where the event occurs and instances where it does not.

As used herein the term “aliphatic radical” refers to an organic radical having a valence of at least one consisting of a linear or branched array of atoms which is not cyclic. Aliphatic radicals are defined to comprise at least one carbon atom. The array of atoms comprising the aliphatic radical may include heteroatoms such as nitrogen, sulfur, silicon, selenium and oxygen or may be composed exclusively of carbon and hydrogen. For convenience, the term “aliphatic radical” is defined herein to encompass, as part of the “linear or branched array of atoms which is not cyclic” a wide range of functional groups such as alkyl groups, alkenyl groups, alkynyl groups, halo alkyl groups, conjugated dienyl groups, alcohol groups, ether groups, aldehyde groups, ketone groups, carboxylic acid groups, acyl groups (for example carboxylic acid derivatives such as esters and amides), amine groups, nitro groups and the like. For example, the 4-methylpent-1-yl radical is a C₆ aliphatic radical comprising a methyl group, the methyl group being a functional group which is an alkyl group. Similarly, the 4-nitrobut-1-yl group is a C₄ aliphatic radical comprising a nitro group, the nitro group being a functional group. An aliphatic radical may be a haloalkyl group which comprises one or more halogen atoms which may be the same or different. Halogen atoms include, for example; fluorine, chlorine, bromine, and iodine. Aliphatic radicals comprising one or more halogen atoms include the alkyl halides trifluoromethyl, bromodifluoromethyl, chlorodifluoromethyl, hexafluoroisopropylidene, chloromethyl; difluorovinylidene; trichloromethyl, bromodichloromethyl, bromoethyl, 2-bromotrimethylene (e.g. —CH₂CHBrCH₂—), and the like. Further examples of aliphatic radicals include allyl, aminocarbonyl (i.e. —CONH₂), carbonyl, dicyanoisopropylidene (i.e. —CH₂C(CN)₂CH₂—), methyl (i.e. —CH₃), methylene (i.e. —CH₂—), ethyl, ethylene, formyl (i.e. —CHO), hexyl, hexamethylene, hydroxymethyl (i.e. —CH₂OH), mercaptomethyl (i.e. —CH₂SH), methylthio (i.e. —SCH₃), methylthiomethyl (i.e. —CH₂SCH₃), methoxy, methoxycarbonyl (i.e. CH₃OCO—), nitromethyl (i.e. —CH₂NO₂), thiocarbonyl, trimethylsilyl (i.e. (CH₃)₃Si—), t-butyldimethylsilyl, trimethoxysilylpropyl (i.e. (CH₃O)₃SiCH₂CH₂CH₂—), vinyl, vinylidene, and the like. By way of further example, a C₁-C₁₀ aliphatic radical contains at least one but no more than 10 carbon atoms. A methyl group (i.e. CH₃—) is an example of a C₁, aliphatic radical. A decyl group (i.e. CH₃(CH₂)₉—) is an example of a C₁₀ aliphatic radical.

As used herein, the term “aromatic radical” refers to an array of atoms having a valence of at least one comprising at least one aromatic group. The array of atoms having a valence of at least one comprising at least one aromatic group may include heteroatoms such as nitrogen, sulfur, selenium, silicon and oxygen, or may be composed exclusively of carbon and hydrogen. As used herein, the term “aromatic radical” includes but is not limited to phenyl, pyridyl, furanyl, thienyl, naphthyl, phenylene, and biphenyl radicals. As noted, the aromatic radical contains at least one aromatic group. The aromatic group is invariably a cyclic structure having 4n+2 “delocalized” electrons where “n” is an integer equal to 1 or greater, as illustrated by phenyl groups (n=1), thienyl groups (n=1), furanyl groups (n=1), naphthyl groups (n=2), azulenyl groups (n=2), anthracenyl groups (n=3) and the like. The aromatic radical may also include nonaromatic components. For example, a benzyl group is an aromatic radical which comprises a phenyl ring (the aromatic group) and a methylene group (the nonaromatic component). Similarly a tetrahydronaphthyl radical is an aromatic radical comprising an aromatic group (C₆H₃) fused to a nonaromatic component —(CH₂)₄—. For convenience, the term “aromatic radical” is defined herein to encompass a wide range of functional groups such as alkyl groups, alkenyl groups, alkynyl groups, haloalkyl groups, haloaromatic groups, conjugated dienyl groups, alcohol groups, ether groups, aldehyde groups, ketone groups, carboxylic acid groups, acyl groups (for example carboxylic acid derivatives such as esters and amides), amine groups, nitro groups, and the like. For example, the 4-methylphenyl radical is a C₇ aromatic radical comprising a methyl group, the methyl group being a functional group which is an alkyl group. Similarly, the 2-nitrophenyl group is a C₆ aromatic radical comprising a nitro group, the nitro group being a functional group. Aromatic radicals include halogenated aromatic radicals such as trifluoromethylphenyl, hexafluoroisopropylidenebis(4-phen-1-yloxy) (i.e. —OPhC(CF₃)₂PhO—), chloromethylphenyl; 3-trifluorovinyl-2-thienyl; 3-trichloromethylphen-1-yl (i.e. 3-CCl₃Ph-), 4-(3-bromoprop-1-yl)phen-1-yl (i.e. BrCH₂CH₂CH₂Ph-), and the like. Further examples of aromatic radicals include 4-allyloxyphen-1-oxy, 4-aminophen-1-yl (i.e. H₂NPh-), 3-aminocarbonylphen-1-yl (i.e. NH₂COPh-), 4-benzoylphen-1-yl, dicyanoisopropylidenebis(4-phen-1-yloxy) (i.e. —OPhC(CN)₂PhO—), 3-methylphen-1-yl, methylenebis(phen-4-yloxy) (i.e. —OPhCH₂PhO—), 2-ethylphen-1-yl, phenylethenyl, 3-formyl-2-thienyl, 2-hexyl-5-furanyl; hexamethylene-1,6-bis(phen-4-yloxy) (i.e. —OPh(CH₂)₆PhO—); 4-hydroxymethylphen-1-yl (i.e. 4-HOCH₂Ph-), 4-mercaptomethylphen-1-yl (i.e. 4-HSCH₂Ph-), 4-methylthiophen-1-yl (i.e. 4-CH₃SPh-), 3-methoxyphen-1-yl, 2-methoxycarbonylphen-1-yloxy (e.g. methyl salicyl), 2-nitromethylphen-1-yl (i.e. -PhCH₂NO₂), 3-trimethylsilylphen-1-yl, 4-t-butyldimethylsilylphenl-1-yl, 4-vinylphen-1-yl, vinylidenebis(phenyl), and the like. The term “a C₃-C₁₀ aromatic radical” includes aromatic radicals containing at least three but no more than 10 carbon atoms. The aromatic radical 1-imidazolyl (C₃H₂N₂—) represents a C₃ aromatic radical. The benzyl radical (C₇H₇—) represents a C₇ aromatic radical.

As used herein the term “cycloaliphatic radical” refers to a radical having a valence of at least one, and comprising an array of atoms which is cyclic but which is not aromatic. As defined herein a “cycloaliphatic radical” does not contain an aromatic group. A “cycloaliphatic radical” may comprise one or more noncyclic components. For example, a cyclohexylmethyl group (C₆H₁₁CH₂—) is a cycloaliphatic radical which comprises a cyclohexyl ring (the array of atoms which is cyclic but which is not aromatic) and a methylene group (the noncyclic component). The cycloaliphatic radical may include heteroatoms such as nitrogen, sulfur, selenium, silicon and oxygen, or may be composed exclusively of carbon and hydrogen. For convenience, the term “cycloaliphatic radical” is defined herein to encompass a wide range of functional groups such as alkyl groups, alkenyl groups, alkynyl groups, halo alkyl groups, conjugated dienyl groups, alcohol groups, ether groups, aldehyde groups, ketone groups, carboxylic acid groups, acyl groups (for example carboxylic acid derivatives such as esters and amides), amine groups, nitro groups and the like. For example, the 4-methylcyclopent-1-yl radical is a C₆ cycloaliphatic radical comprising a methyl group, the methyl group being a functional group which is an alkyl group. Similarly, the 2-nitrocyclobut-1-yl radical is a C₄ cycloaliphatic radical comprising a nitro group, the nitro group being a functional group. A cycloaliphatic radical may comprise one or more halogen atoms which may be the same or different. Halogen atoms include, for example; fluorine, chlorine, bromine, and iodine. Cycloaliphatic radicals comprising one or more halogen atoms include 2-trifluoromethylcyclohex-1-yl, 4-bromodifluoromethylcyclooct-1-yl, 2-chlorodifluoromethylcyclohex-1-yl, hexafluoroisopropylidene2,2-bis(cyclohex-4-yl) (i.e. —C₆H₁₀C(CF₃)₂C₆H₁₀—), 2-chloromethylcyclohex-1-yl; 3-difluoromethylenecyclohex-1-yl; 4-trichloromethylcyclohex-1-yloxy, 4-bromodichloromethylcyclohex-1-ylthio, 2-bromoethylcyclopent-1-yl, 2-bromopropylcyclohex-1-yloxy (e.g. CH₃CHBrCH₂C₆H₁₀—), and the like. Further examples of cycloaliphatic radicals include 4-allyloxycyclohex-1-yl, 4-aminocyclohex-1-yl (i.e. H₂C₆H₁₀—), 4-aminocarbonylcyclopent-1-yl (i.e. NH₂COC₅H₈—), 4-acetyloxycyclohex-1-yl, 2,2-dicyanoisopropylidenebis(cyclohex-4-yloxy) (i.e. —OC₆H₁₀C(CN)₂C₆H₁₀O—), 3-methylcyclohex-1-yl, methylenebis(cyclohex-4-yloxy) (i.e. —OC₆H₁₀CH₂C₆H₁₀O—), 1-ethylcyclobut-1-yl, cyclopropylethenyl, 3-formyl-2-terahydrofuranyl, 2-hexyl-5-tetrahydrofuranyl; hexamethylene-1,6-bis(cyclohex-4-yloxy) (i.e. —O C₆H₁₀(CH₂)₆C₆H₁₀O—); 4-hydroxymethylcyclohex-1-yl (i.e. 4-HOCH₂C₆H₁₀—), 4-mercaptomethylcyclohex-1-yl (i.e. 4-HSCH₂C₆H₁₀—), 4-methylthiocyclohex-1-yl (i.e. 4-CH₃SC₆H₁₀O—), 4-methoxycyclohex-1-yl, 2-methoxycarbonylcyclohex-1-yloxy (2-CH₃OCOC₆H₁₀O—), 4-nitromethylcyclohex-1-yl (i.e. NO₂CH₂C₆H₁₀—), 3-trimethylsilylcyclohex-1-yl, 2-t-butyldimethylsilylcyclopent-1-yl, 4-trimethoxysilylethylcyclohex-1-yl (e.g. (CH₃O)₃SiCH₂CH₂C₆H₁₀—), 4-vinylcyclohexen-1-yl, vinylidenebis(cyclohexyl), and the like. The term “a C₃-C₁₀ cycloaliphatic radical” includes cycloaliphatic radicals containing at least three but no more than 10 carbon atoms. The cycloaliphatic radical 2-tetrahydrofuranyl (C₄H₇O—) represents a C₄ cycloaliphatic radical. The cyclohexylmethyl radical (C₆H₁₁CH₂—) represents a C₇ cycloaliphatic radical.

The term “electrical structure” refers to an assembly comprising a curable flowable thermally conductive material, a heat dissipating element, and a substrate linked to a semiconductor chip via at least one electrical interconnect.

The term “curable flowable thermally conductive material” refers to a thermally conductive composition which may be a partially cured material or an uncured material. Curable flowable thermally conductive materials which have been partially cured are referred to at times herein as “B-staged” materials. After curing, the curable flowable thermally conductive material may at times be referred to as the “cured thermally conductive material”.

In various embodiments of the invention the curable flowable thermally conductive material is caused to fill at least a portion of an interlayer zone defined by the substrate, the semiconductor chip and the at least one electrical interconnect. Causing the curable flowable thermally conductive material to fill the interlayer zone may be brought about by heating, for example, (or other means discussed herein) the electrical structure, optionally under pressure.

As used herein, the term “electronic device” refers to an assembly comprising a cured thermal interface material prepared by curing a curable flowable thermally conductive material, a heat dissipating element, a substrate linked to a semiconductor chip via at least one electrical interconnect. Electronic devices are illustrated by Chip Scale Packages (CSPs), Ball Grid Arrays (BGAs), MicroLeadFrame (MLF) devices, Flip Chip BGAs (FCBGAs), and the like

As used herein, the expression “substantially free of sealant material” refers to an electronic device (as defined herein) which does not comprise a second adhesive material as a sealant joining the heat dissipating element to the substrate. When the electronic device is substantially free of sealant material, the only adhesive used to join the heat dissipating element to the substrate is the cured thermally conductive material itself.

As noted, in one aspect the invention provides a method of forming an electronic device, said method comprising the steps (A), (B) and (C):

(A) providing a substrate linked to a semiconductor chip via at least one electrical interconnect, said substrate and said semiconductor chip and said at least one electrical interconnect defining an interlayer zone;

(B) coating a predetermined portion of a heat dissipating element with a curable flowable thermally conductive material to provide a coated heat dissipating element; and

(C) joining the coated heat dissipating element with the semiconductor chip to provide an electrical structure comprising a heat dissipating element, a substrate linked to a semiconductor chip via at least one electrical interconnect, said electrical structure comprising an interlayer zone defined by the substrate, the electrical interconnect, and the semiconductor chip, and causing the curable flowable thermally conductive material to fill at least a portion of said interlayer zone and subsequently curing the curable flowable thermally conductive material.

In one embodiment the method of the present invention comprises steps (A), (B), and (C) and affords an electronic device which is substantially free of sealant material. In an alternate embodiment, the method of the present invention comprises steps (A), (B), and (C) and affords an electronic device which comprises a sealant. In one embodiment, the sealant joins the heat dissipating element to the substrate.

In step (A) a substrate linked to a semiconductor chip via at least one electrical interconnect is provided. The substrate linked to the semiconductor chip comprises an interlayer zone defined by the substrate, the semiconductor chip and the at least one electrical interconnect. This interlayer zone may also be referred to as a gap. Structures contemplated in this step (Step (A)) comprising a substrate linked to a semiconductor chip via at least one electrical interconnect are well known to those skilled in the art and are available commercially.

In step (B) a predetermined portion of a heat dissipating element is coated with a curable flowable thermally conductive material to provide a coated heat dissipating element. The curable flowable thermally conductive material may be any thermally conductive material which can be caused to flow, and such materials are available commercially or can be prepared by methods known to those skilled in the art. The curable flowable thermally conductive material may be a partially cured (B-staged) thermally conductive material which can caused to flow. Thus in one aspect a predetermined portion of a heat dissipating element is coated with a B-staged curable flowable thermally conductive material which tends not to flow under ambient conditions but does flow upon the application of heat, pressure or a combination of heat and pressure.

In step (C) the coated heat dissipating element is joined to the semiconductor chip to provide an electrical structure. The curable flowable thermally conductive material is caused to flow and cure to provide the electronic device. As the curable flowable thermally conductive material flows, it fills at least a portion of the interlayer zone defined by the substrate, the semiconductor chip and the at least one electrical interconnect.

As noted, in an alternate embodiment the present invention provides a method of forming an electronic device via a method comprising Steps (A)-(E) detailed below. The application of steps (A)-(E) according to the method of the present invention affords an electronic device which is substantially free of sealant material.

In step (A) a substrate linked to a semiconductor chip via at least one electrical interconnect is provided. The substrate linked to the semiconductor chip comprises an interlayer zone defined by the substrate, the semiconductor chip and the at least one electrical interconnect.

In step (B) at least a portion of the interlayer zone is filled with a curable flowable thermally conductive material.

In step (C) a predetermined portion of the semiconductor chip is coated with the curable flowable thermally conductive material.

In step (D) the structure elaborated by steps (A)-(C) is joined to a heat dissipating element to provide an electrical structure.

In step (E) the curable flowable thermally conductive material is subjected to conditions which result in its being cured, for example heating the electrical structure formed in step (D) to a suitable temperature at which curing of the curable flowable thermally conductive material occurs.

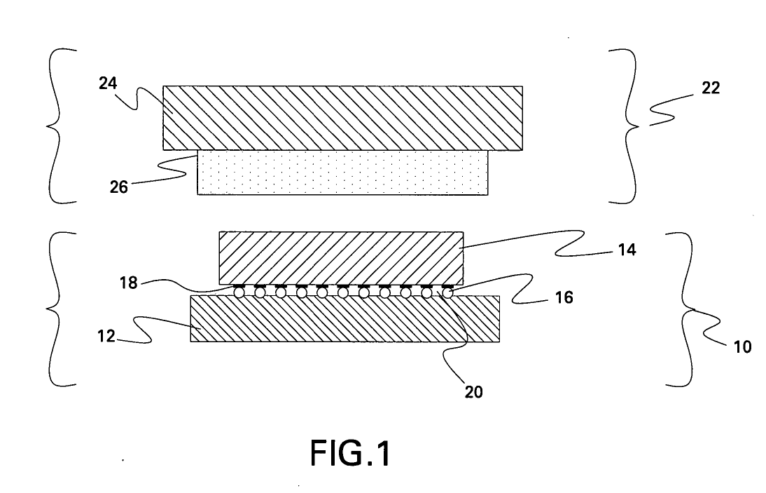

Referring to the drawings, FIGS. 1, 2, and 3 illustrate the formation of an electronic device comprising an exemplary Flip-Chip Assembly. In FIG. 1, a first assembly 10 is shown which comprises a substrate 12 that is linked to the semiconductor chip 14 via at least one electrical interconnect 16. The semiconductor chip 14 may comprise a variety of semiconductor materials such as silicon metal, silicon carbide, gallium nitride and the like. The at least one electrical interconnect typically comprises standard solder ball made of a eutectic tin-lead composition (for example a composition comprising about 63 percent tin and about 37 percent lead (63Sn/37Pb)) or a lead-free (tin-silver, tin-silver-copper, tin-copper) composition, though other compositions are known and used by those of ordinary skill in the art. Furthermore, a pad 18 may be present between the semiconductor chip 14 and each of the at least one electrical interconnects 16. The substrate 12 and the semiconductor chip 14 may further comprise other attachments such as pad landings, passivation layers, redistribution layers and the like that are not shown in this exemplary illustration. The substrate 12, the semiconductor chip 14, and the electrical interconnects 16 define an “interlayer zone”, depicted in FIG. 1 as component 20.

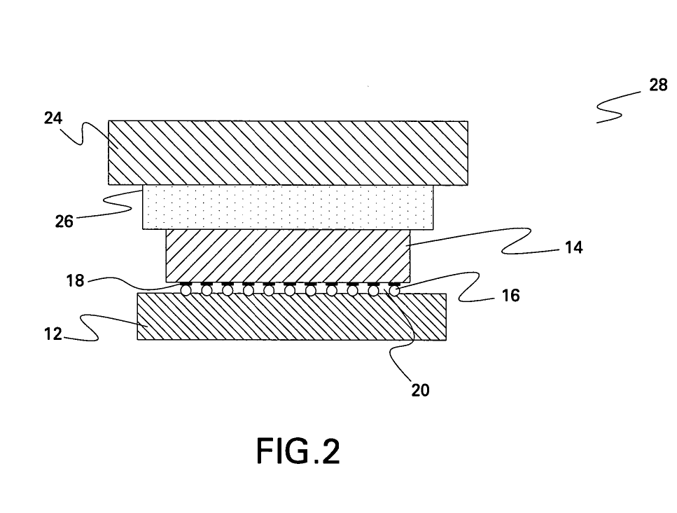

Also shown in FIG. 1 is a second assembly 22 comprising a heat dissipating element 24 that is coated on one side with a curable flowable thermally conductive material 26. The heat dissipating element may be made of any thermally conductive material. For example, the heat dissipating element may comprise one or more thermally conductive materials such as aluminum, copper, silver, diamond, and the like. In addition, the heat dissipating element may contain an outer protective finish such as chromate finish for aluminum heat dissipating elements and nickel finish for copper heat dissipating elements. In this exemplary illustration, the curable flowable thermally conductive material 26 is used in an amount such that it will completely coat the semiconductor chip 14 on at least one side when the first assembly 10 is joined to the second assembly 22 to form a first electrical structure 28 (See FIG. 2). The curable flowable thermally conductive material 26 is typically a solid or a viscous gel. In a typical embodiment, the curable flowable thermally conductive material is partially cured (‘B-staged’) after coating the heat dissipating element. In another embodiment, the curable flowable thermally conductive material is B-staged prior to the coating of the heat dissipating element.

FIG. 2 illustrates the first electrical structure 28 formed by joining first assembly 10 with the second assembly 22.

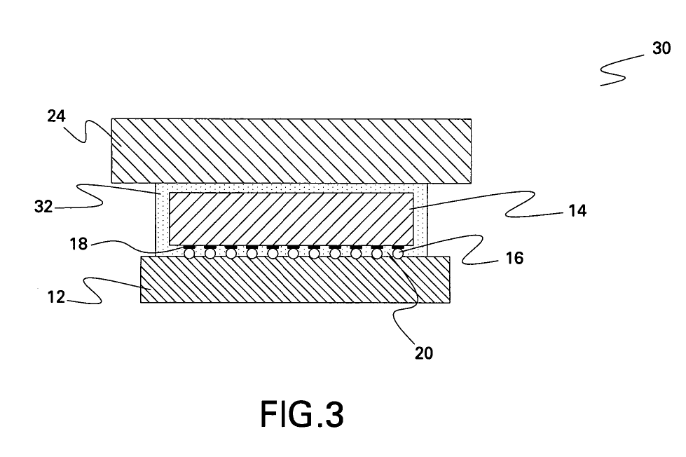

FIG. 3 illustrates the formation of a first electronic device 30 after curing the curable flowable thermally conductive material 26 in first electrical structure 28 (shown in FIG. 2) to form a cured thermally conductive material 32. In one embodiment, during the curing step, the curable flowable thermally conductive material flows and completely fills the interlayer zone 20 present between the substrate 12 and the semiconductor chip 14. In another embodiment, during the curing step, the curable flowable thermally conductive material flows such that the interlayer zone 20 is only partially filled. In a further embodiment, the electrical structure is formed and then the curable flowable thermally conductive material is subjected to a curing step. The cured material 32 functions as both a thermal interface material (TIM) and an underfill material. Thermal interface materials play an important role in electronic applications in that they aid in the dissipation of heat that might otherwise build-up inside the device. Underfill materials are necessary to provide support to the at least one electrical interconnect so that the life and/or the robustness of the device may be increased.

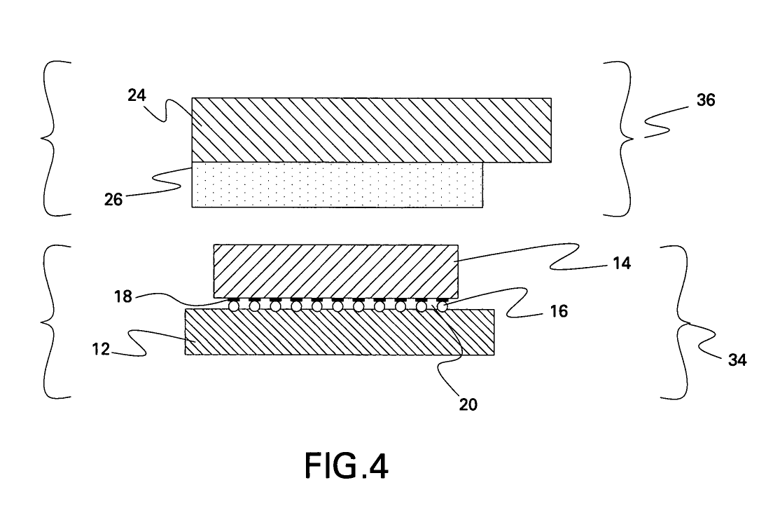

FIGS. 4-6 illustrate another embodiment of the invention which shows the steps involved in forming an exemplary Flip-Chip Assembly. In FIG. 4, a third assembly 34 is shown which comprises a substrate 12 is linked to a semiconductor chip 14 via a plurality of electrical interconnects 16, wherein the semiconductor chip 14 is linked to each of the electrical interconnect 16 via attachment pads 18. The substrate 12 and the semiconductor chip 14 may further comprise other attachments such as pad landings, passivation layers, redistribution layers and the like that are not shown in this simplified exemplary illustration. In one embodiment, the substrate 12, the semiconductor chip 14, the electrical interconnects 16, the pads 18 define an interlayer zone, depicted in FIG. 4 as 20. In other embodiments, the interlayer zone is further characterized by additional attachments present within or adjacent to the interlayer zone.

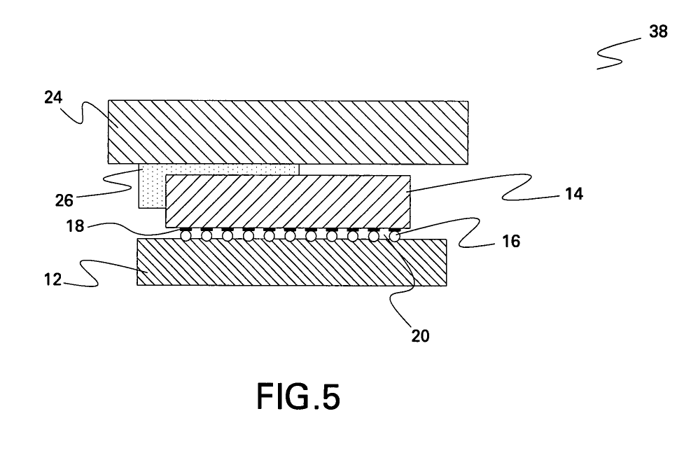

Also shown in FIG. 4 is a fourth assembly 36 which comprises a heat dissipating element 24 wherein only a portion of the heat dissipating element 24 is coated with a curable flowable thermally conductive material 26. In the embodiment shown in FIG. 5, the amount of the curable flowable thermally conductive material 26 used is such that when third assembly 34 (FIG. 4) is joined to fourth assembly 36 (FIG. 4) to form a second electrical structure 38 (FIG. 5), the curable flowable thermally conductive material 26 is in contact with only a portion of the semiconductor chip 14. The second electrical structure 38 may be subjected to a curing step during which the curable flowable thermally conductive material 26 is caused to flow and cure. In one embodiment, the curable flowable thermally conductive material 26 fills the interlayer zone 20 such that the semiconductor chip 14 is completely encapsulated by the curable flowable thermally conductive material 26.

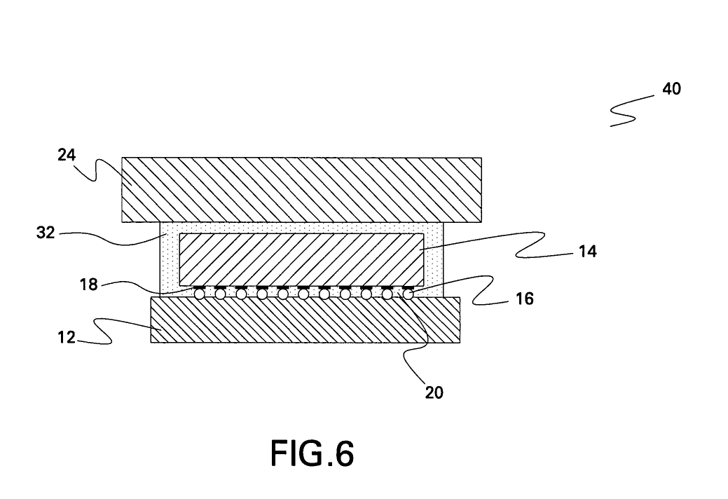

FIG. 6 shows a second electronic device 40 in which the cured thermally conductive material 32 completely encapsulates the semiconductor chip 14. Thus, subjecting the second electronic device structure 38 shown in FIG. 5 to curing conditions causes the curable flowable thermally conductive material 26 to flow and encapsulate the semiconductor chip 14. During the curing process the curable flowable thermally conductive material 26 is transformed into the cured thermally conductive material 32. In one embodiment, during the curing step, the curable flowable thermally conductive material 26 flows and encapsulates the semiconductor chip 14 (i.e. completely covers the top and sides of the semiconductor chip 14 and completely fills the interlayer zone 20. Thus the cured curable flowable thermally conductive material 32 serves both as the thermal interface material (TIM) as well as the underfill material.

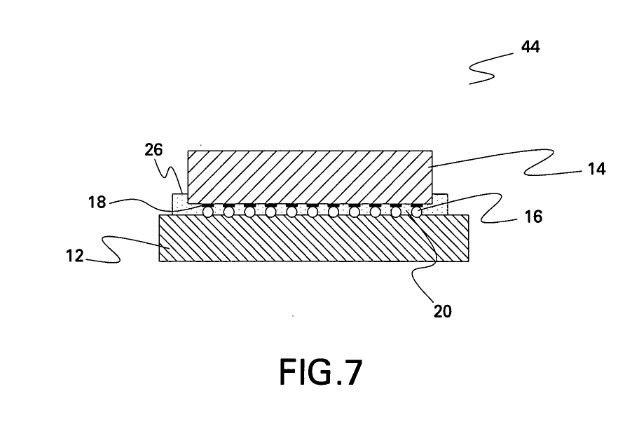

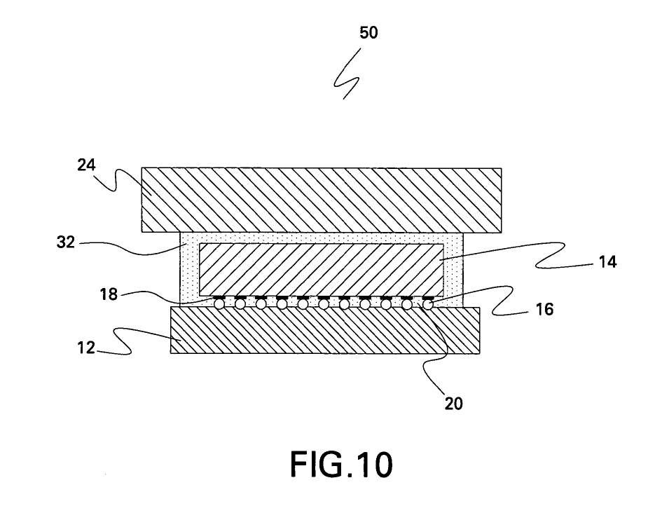

FIGS. 7-10 illustrate a further embodiment of the invention which shows the steps involved in forming an exemplary third electronic device 50 which is a Flip-Chip Assembly (FIG. 10). FIG. 7 shows a fifth assembly 44 which comprises a substrate 12 that is linked to a semiconductor chip 14 via at least one electrical interconnect 16. The semiconductor chip 14 contacts the electrical interconnects 16 via pads 18. The substrate 12 and the semiconductor chip 14 may further comprise other attachments such as pad landings, passivation layers, redistribution layers etc. that are not shown in this simplified exemplary illustration. The substrate 12, the semiconductor chip 14, the electrical interconnects 16, the pads 18, and any other attachments present within or adjacent to the interlayer zone define an interlayer zone 20, depicted in FIG. 7. The interlayer zone 20 is filled with a curable flowable thermally conductive material 26. The curable flowable thermally conductive material may be added to the assembly using suitable techniques known to those of ordinary skill in the art, such techniques include, but are not limited to dispensing, capillary underfilling, printing, and the like.

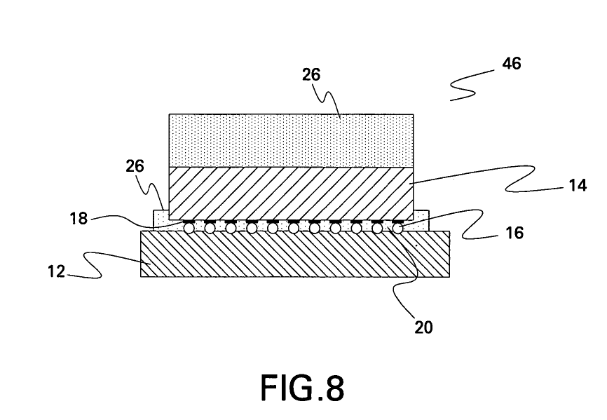

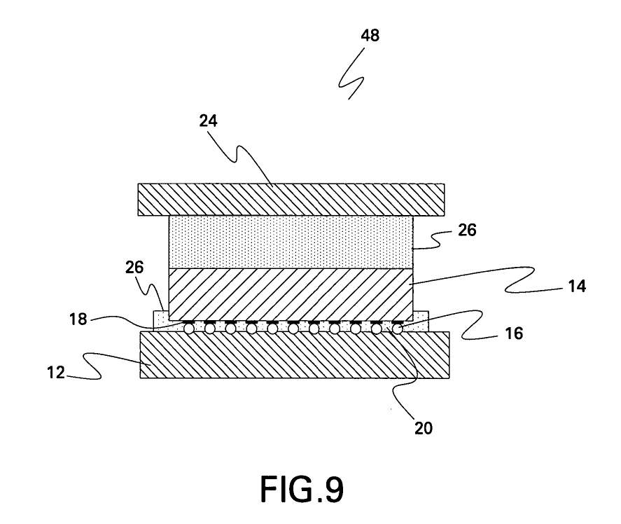

FIG. 8 shows a sixth assembly 46 which is elaborated from the assembly 44 depicted in FIG. 7 wherein the upper surface (the surface opposite the interlayer zone 20) of semiconductor chip 14 is independently coated with the curable flowable thermally conductive material 26. A variety of methods, such as those known in the art, may be used to coat the semiconductor chip 14. The layer of the curable flowable thermally conductive material 26 on the upper surface of the semiconductor chip may completely coat the upper surface of the semiconductor chip or may coat only a portion of the upper surface of semiconductor chip 14. FIG. 9 shows a third electrical structure 48 wherein heat dissipating element 24 is joined to the sixth assembly 46 shown in FIG. 8. Finally, FIG. 10 shows a third electronic device 50 wherein the third electrical structure 48 shown in FIG. 9 has been subjected to curing conditions causing the curable flowable thermally conductive material 26 (FIG. 9) to flow and subsequently cure. In the embodiment shown in FIG. 10, the semiconductor chip has been completely encapsulated, and the curable flowable thermally conductive material 26 has been transformed by the curing process into the cured thermally conductive material 32. In another embodiment, during the curing step, the curable flowable thermally conductive material flows such that only a portion of the semiconductor chip 14 is in contact with the cured thermally conductive material 32. As illustrated in FIG. 10, the cured thermally conductive material 32 serves as a thermal interface between the semiconductor chip and the heat dissipating element, as well as the underfill material which occupies the interlayer zone 20.

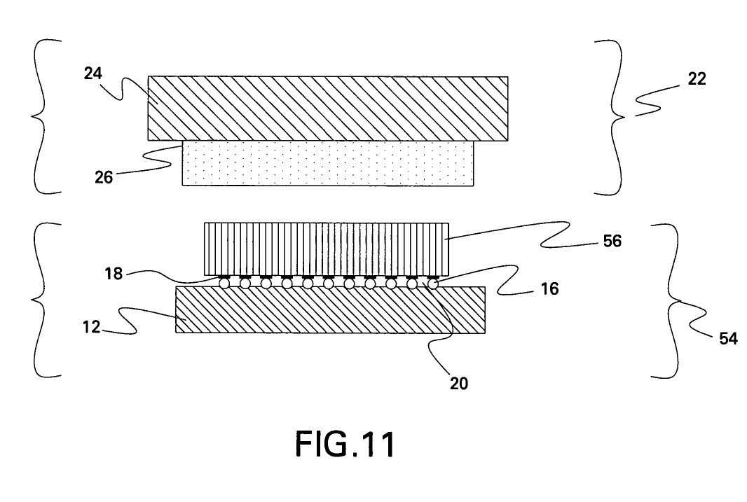

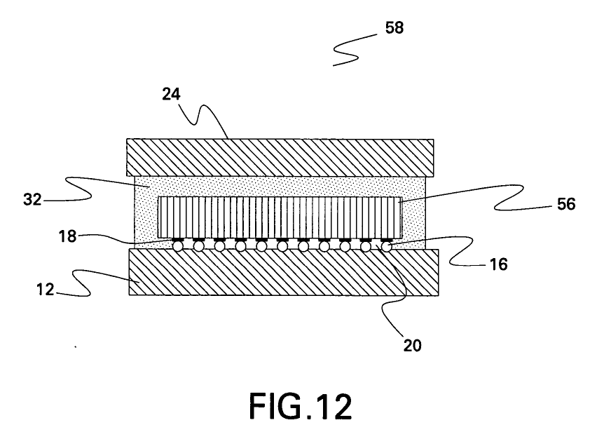

FIGS. 11-12 illustrate an embodiment of the invention which shows the steps involved in forming an exemplary fourth electronic device 58 (FIG. 12) comprising a Wafer Level Chip Scale Packaging (WLCSP) component 56 and a substrate 12 linked thereto via at least one electrical interconnect 16. The at least one electrical interconnect typically may comprise standard eutectic tin-lead (63Sn/37Pb) or lead-free (tin-silver, tin-silver-copper, tin-copper) compositions, though other compositions are known and used by those of ordinary skill in the art. Pads 18 may be present linking the WLCSP 56 and electrical interconnects 16. Typically, pads such as those designated component 18 in FIG. 11 and FIG. 12 are incorporated in the WLCSP. The substrate 12 and the WLCSP 56 may further comprise other attachments such as pad landings, passivation layers, redistribution layers etc. that are not shown in this simplified exemplary illustration. The substrate 12, the WLCSP 56, the electrical interconnects 16, the pads 18, and any other attachments present in the assembly define an interlayer zone, depicted in FIG. 11 as 20.

Also shown in FIG. 11 is a second assembly 22 comprising a heat dissipating element 24 that is coated on one side with a curable flowable thermally conductive material 26. The heat dissipating element may be made of any thermally conducting material such as aluminum, copper and the like. In addition, the heat dissipating element may contain an outer protective finish such as chromate finish for aluminum and nickel finish for copper. In this exemplary illustration (FIG. 12), the curable flowable thermally conductive material is used in an amount such that it completely coats the WLCSP 56 on at least one side. In one embodiment the curable flowable thermally conductive material 26 is a solid or a viscous gel. In one embodiment, the curable flowable thermally conductive material is partially cured (‘B-staged’) after coating the heat dissipating element. In another embodiment, the B-staging is done prior to the coating of the heat dissipating element.

FIG. 12 illustrates a fourth electronic device 58 which comprising a WLCSP component 56. Electronic device 58 is formed by joining the second assembly 22 with the seventh assembly 54 to form an electrical structure which when subjected to curing conditions affords the WLCSP-containing electronic device 58 wherein the cured thermally conductive material 32 is present on all sides of the WLCSP 56 such that at least a portion of the interlayer zone 20 contains the cured thermally conductive material 32. In another embodiment (not shown), during the curing step, the curable flowable thermally conductive material flows and completely fills the interlayer zone 20 present between the substrate 12 and the WLCSP 56 during the curing step. In the embodiment shown in FIG. 12, the curable flowable thermally conductive material has been caused to flow such that the interlayer zone 20 is only partially filled. In yet another embodiment, during the curing step, the curable flowable thermally conductive material flows only to the bottom edge of the WLCSP thus leaving the interlayer zone 20 essentially unfilled. In a further embodiment, the electrical structure is formed and then the curable flowable thermally conductive material is subjected to a curing step. The cured thermally conductive material 32 functions as a thermal interface material between the WLSCP 56 and the heat dissipating unit 24, The cured thermally conductive material 32 also functions as an underfill material which provides greater structural integrity of the interface between the substrate, the electrical interconnects, and the WLSCP.

In one embodiment, at least one electronic device provided by the present invention is comprised within an electronic system, such as for example a cell phones, video games, computers, global positioning devices, medical diagnostic devices, video cassette recorders, audio systems, public address systems, CD players, DVD players, hand held remote control devices, television sets, radios, and the like.

In one embodiment the present invention provides a system comprising at least one electronic device prepared by a method, the method comprising providing a substrate linked to a semiconductor chip via at least one electrical interconnect, said substrate and said semiconductor chip and said at least one electrical interconnect defining an interlayer zone; coating a predetermined portion of a heat dissipating element with a curable flowable thermally conductive material, B-staging (i.e. partially curing) the curable flowable thermally conductive material to provide a coated heat dissipating element; joining the coated heat dissipating element with the semiconductor chip to provide an electrical structure comprising a heat dissipating element, a substrate linked to a semiconductor chip via at least one electrical interconnect; said electrical structure comprising an interlayer zone defined by the substrate, the electrical interconnect, and the semiconductor chip; and causing the curable flowable thermally conductive material to fill at least a portion of said interlayer zone and subsequently curing the curable flowable thermally conductive material.

In another embodiment the present invention provides a system comprising at least one electronic device comprising a substrate; a semiconductor chip that is linked to the substrate via at least one electrical interconnect, said substrate and said semiconductor chip and said at least one electrical interconnect defining an interlayer zone; a heat dissipating element; and a cured thermally conductive material that forms a thermal interface layer between the heat dissipating element and the semiconductor chip, said cured thermally conductive material also occupying at least a portion of said interlayer zone, said electronic device being substantially free of sealant material other than the cured thermally conductive material joining the heat dissipating element to the substrate.

In yet another embodiment, the present invention provides a system comprising at least one electronic device, said electronic device being prepared by a method, said method comprising providing a substrate linked to a semiconductor chip via at least one electrical interconnect, said substrate and said semiconductor chip and said at least one electrical interconnect defining an interlayer zone; filling at least a portion of said interlayer zone with a curable flowable thermally conductive material; coating a predetermined portion of the semiconductor chip; joining a structure formed by steps (A)-(C) to a heat dissipating element; and curing the curable flowable thermally conductive material, said electronic device being substantially free of sealant material other than the cured thermally conductive material joining the heat dissipating element to the substrate.

In one embodiment, the curable flowable thermally conductive material comprises at least one epoxy resin, at least one particulate filler, at least one cure catalyst, and optional reagents.

Epoxy resins as described in the invention are curable monomers and oligomers that include any organic system or inorganic system with an epoxy functionality. The epoxy resins useful in the invention include those described in “Chemistry and technology of the Epoxy Resins,” B. Ellis (Ed.) Chapman Hall 1993, New York and “Epoxy Resins Chemistry and Technology,” C. May and Y. Tanaka, Marcell Dekker 1972, New York. Epoxy resins that can be used for the invention include those that could be produced by reaction of a hydroxyl, carboxyl or amine containing compound with epichlorohydrin, preferably in the presence of a basic catalyst, such as a metal hydroxide, for example sodium hydroxide. Also included are epoxy resins produced by reaction of a compound containing at least one and preferably two or more carbon-carbon double bonds with a peroxide, such as a peroxyacid.

Epoxy resins which may be used in the practice of the present invention include cycloaliphatic and aliphatic epoxy resins. Aliphatic epoxy resins include compounds that contain at least one aliphatic group and at least one epoxy group. Examples of aliphatic epoxy resins include butadiene oxide, dimethylpentane dioxide, diglycidyl ether, 1,4-butanediol glycidyl ether, diethylene glycol diglycidyl ether, and dipentene dioxide.

Cycloaliphatic epoxy resins are well known to the art and, as described herein, are compounds that contain at least about one cycloaliphatic group and at least one oxirane group. In one embodiment, the cycloalipahtic epoxy resin comprises compounds that contain at least one cycloaliphatic group and at least two oxirane rings per molecule. Specific examples include 3-cyclohexenylmethyl-3-cyclohexenylcarboxylate diepoxide; 2-(3,4-epoxy)cyclohexyl-5,5-spiro-(3,4-epoxy)cyclohexane-m-dioxane; 3,4-epoxycyclohexylalkyl-3,4-epoxycyclohexanecarboxylate; 3,4-epoxy-6-methylcyclohexylmethyl-3,4-epoxy-6-methylcyclohexanecarboxylate; vinyl cyclohexanedioxide, bis(3,4-epoxycyclohexylmethyl)adipate; bis(3,4-epoxy-6-methylcyclohexylmethyl)adipate; exo-exo bis(2,3-epoxycyclopentyl)ether; endo-exo bis(2,3-epoxycyclopentyl)ether; 2,2-bis(4-(2,3-epoxypropoxy)cyclohexyl)propane; 2,6-bis(2,3-epoxypropoxycyclohexyl-p-dioxane); 2,6-bis(2,3-epoxypropoxy)norbornene; the diglycidylether of linoleic acid dimmer; limonene dioxide; 2,2-bis(3,4-epoxycyclohexyl)propane; dicyclopentadiene dioxide; 1,2-epoxy-6-(2,3-epoxypropoxy)hexahydro-4,7-methanoindane; p-(2,3-epoxy)cyclopentylphenyl-2,3-epoxypropylether; 1-(2,3-epoxypropoxy)phenyl-5,6-epoxyhexahydro-4,7-methanoindane; o-(2,3-epoxy)cyclopentylphenyl-2,3-epoxypropyl ether); 1,2-bis(5-(1,2-epoxy)-4,7-hexahydromethanoindanoxyl)ethane; cyclopentenylphenyl glycidyl ether; cyclohexanediol diglycidyl ether; and diglycidyl hexahydrophthalate.

Aromatic epoxy resins may also be used with the invention. Examples of epoxy resins useful in the invention include bisphenol-A epoxy resins, bisphenol-F epoxy resins, phenol novolac epoxy resins, cresol-novolac epoxy resins, biphenol epoxy resins, biphenyl epoxy resins, 4,4′-biphenyl epoxy resins, polyfunctional epoxy resins, divinylbenzene dioxide, and 2-glycidylphenylglycidyl ether. When resins, including aromatic, aliphatic and cycloaliphatic resins, are described throughout the specification and claims, either the specifically-named resin or molecules having a moiety of the named resin are envisioned.

Silicone-epoxy resins of the invention typically have the formula:
MₐM′_{b}D_{c}D′_{d}TₑT′_{f}Q_{g}
wherein the subscripts a, b, c, d, e, f and g are zero or a positive integer, subject to the limitation that the sum of the subscripts b, d and f is one or greater; where M has the formula:
R¹₃SiO_{1/2},

M′ has the formula:
(Z)R²₂SiO_{1/2},

D has the formula:
R³₂SiO_{2/2},

D′ has the formula:
(Z)R⁴SiO_{2/2},

T has the formula:
R⁵SiO_{3/2},

T has the formula:
(Z)SiO_{3/2},
and Q has the formula SiO_{4/2}, where each R¹, R², R¹, R⁴, R⁵ is independently at each occurrence a hydrogen atom, C₁₋₂₂ aliphatic radical or a C₆₋₁₄ aromatic radical, and Z, independently at each occurrence, represents an epoxy group. Combinations of epoxy monomers and oligomers may be used in the invention. In one embodiment the curable flowable thermally conductive material comprises an epoxy resin which is a cresol novolac epoxy resin available commercially as ECN from Sumitomo Chemicals Ltd., Japan.

In one embodiment, the curable flowable thermally conductive material comprises a particulate filler. The particulate filler may be selected from the group consisting of fused silica, fumed silica, colloidal silica, aluminum, alumina, boron nitride, aluminum nitride, silicon nitride, kaolin, quartz powder, carbon black, aluminum, alumina, copper, silver, gold, platinum, palladium, boron, beryllium, rhodium, nickel, cobalt, iron, molybdenum, tin, lead, chromium, zinc, magnesium, tungsten, bismuth, cadmium, gallium, indium, mercury, antimony, scandium, polonium, antimony oxide, iron oxide, zinc oxide, nickel oxide, silver oxide and combinations thereof. In a particular embodiment of the invention, the filler is functionalized colloidal silica. Colloidal silica is a dispersion of submicron-sized silica (SiO₂) particles in an aqueous or other solvent medium. The colloidal silica contains up to about 85 weight % of silicon dioxide (SiO₂) and more typically up to about 80 weight % of silicon dioxide. The particle size of the colloidal silica is typically in a range between about 1 nanometers (nm) and about 250 nm, and more typically in a range between about 5 nm and about 150 nm.

The colloidal silica may be functionalized with an organoalkoxysilane to form an organofunctionalized colloidal silica. Organoalkoxysilanes used to functionalize the colloidal silica are included within the formula:
(R⁷)ₕSi(OR⁸)₄₋ₕ,
where R⁷ is independently at each occurrence a C₁-C₁₈ monovalent aliphatic radical or C₆-C₁₄ aromatic radical, R⁸ is independently at each occurrence a C₁-C₁₈ monovalent aliphatic radical, a monovalent aromatic radical, a monovalent cycloaliphatic radical or a hydrogen radical and “h” is a whole number ranging from to 1 to 3 inclusive. Preferably, the organoalkoxysilanes included in the invention are 2-(3,4-epoxy cyclohexyl)ethyltrimethoxysilane, 3-glycidoxypropyltrimethoxysilane, phenyltrimethoxysilane, and methacryloxypropyltrimethoxysilane. A combination of functionality is possible. Typically, the organoalkoxysilane is present in a range between about 5 weight % and about 60 weight % based on the weight of silicon dioxide contained in the colloidal silica. The resulting organofunctionalized colloidal silica can be treated with an acid or base to modify its properties. An acid, a base, or other catalyst effective at promoting condensation of silanol and alkoxysilane groups may also be used to aid the functionalization process. Such catalysts include organo-titanium compounds such as tetrabutyl titanate, and titanium isopropoxybis(acetylacetonate). Suitable catalysts also include and organo-tin compounds such as dibutyltin dilaurate. In one embodiment the catalyst comprises a combination of at least one organo-titanium compound and at least one organotin compound.

The functionalization of the colloidal silica may be performed by adding the organoalkoxysilane functionalization agent to an aqueous dispersion of colloidal silica to which an aliphatic alcohol has been added. The resulting composition comprising the functionalized colloidal silica and the organoalkoxysilane functionalization agent in the aliphatic alcohol is defined herein as a pre-dispersion. The aliphatic alcohol is typically an aliphatic alcohol selected from the group consisting of isopropanol, t-butanol, 2-butanol, and combinations thereof. The amount of aliphatic alcohol is typically employed in an amount corresponding to from about 1 fold to about 10 fold by weight of the amount of silicon dioxide present in the aqueous colloidal silica pre-dispersion. In some cases, stabilizers such as 4-hydroxy-2,2,6,6-tetramethylpiperidinyloxy (i.e. 4-hydroxy TEMPO) may be added to this pre-dispersion. In some instances small amounts of acid or base may be added to adjust the pH of the transparent pre-dispersion. “Transparent” as used herein refers to a maximum haze value of 15%, typically a maximum haze value of 10%; and most typically a maximum haze value of 3%, as measured by the standard test method described in ASTM D1003. The resulting pre-dispersion is typically heated from about 50° C. to about 100° C. for a period of from about 1 hour to about 5 hours.

The cooled transparent organic pre-dispersion is then further treated to form a final dispersion of the functionalized colloidal silica by addition of curable epoxy monomers or oligomers and optionally, a solvent which may be selected from but not limited to isopropanol, 1-methoxy-2-propanol, 1-methoxy-2-propyl acetate, toluene, and combinations thereof. This final dispersion of the functionalized colloidal silica may be treated with acid or base or with ion exchange resins to remove acidic or basic impurities. This final dispersion of the functionalized colloidal silica is then concentrated under a vacuum in a range between about 0.5 Torr and about 250 Torr and at a temperature in a range between about 20° C. and about 140° C. to substantially remove any low boiling components such as solvent, residual water, and combinations thereof to give a transparent dispersion of functionalized colloidal silica in a curable epoxy monomer, herein referred to as a final concentrated dispersion. Substantial removal of low boiling components is defined herein as removal of at least about 90% of the total amount of low boiling components.

In some instances, the pre-dispersion or the final dispersion of the functionalized colloidal silica may be further functionalized. Low boiling components are at least partially removed and subsequently, an appropriate capping agent that will react with residual hydroxyl functionality of the functionalized colloidal silica is added in an amount in a range between about 0.05 times and about 10 times the amount by weight of silicon dioxide present in the pre-dispersion or final dispersion. Partial removal of low boiling components as used herein refers to removal of at least about 10% of the total amount of low boiling components, and preferably, at least about 50% of the total amount of low boiling components. An effective amount of capping agent caps the functionalized colloidal silica and capped functionalized colloidal silica is defined herein as a functionalized colloidal silica in which at least 10%, preferably at least 20%, more preferably at least 35%, of the free hydroxyl groups present in the corresponding uncapped functionalized colloidal silica have been functionalized by reaction with a capping agent.

Exemplary capping agents include hydroxyl reactive materials such as silylating agents. Examples of silylating agents include, but are not limited to hexamethyldisilazane (HMDZ), tetramethyldisilazane, divinyltetramethyldisilazane, diphenyltetramethyldisilazane, N-(trimethylsilyl)diethylamine, 1-(trimethylsilyl)imidazole, trimethylchlorosilane, pentamethylchlorodisiloxane, pentamethyldisiloxane, and combinations thereof. The transparent dispersion is then heated in a range between about 20° C. and about 140° C. for a period of time in a range between about 0.5 hours and about 48 hours. The resultant mixture is then filtered. If the pre-dispersion was reacted with the capping agent, at least one curable epoxy monomer is added to form the final dispersion. The mixture of the functionalized colloidal silica in the curable monomer is concentrated at a pressure in a range between about 0.5 Torr and about 250 Torr to form the final concentrated dispersion. During this process, lower boiling components such as solvent, residual water, byproducts of the capping agent and hydroxyl groups, excess capping agent, and combinations thereof are substantially removed.

In order to form the total curable epoxy formulation, a cure catalyst is added to the final concentrated dispersion. Cure catalysts accelerate curing of the total curable epoxy formulation. Typically, the catalyst is present in a range between about 10 parts per million (ppm) and about 10% by weight of the total curable epoxy formulation. Examples of cure catalysts include, but are not limited to, onium catalysts such as bisaryliodonium salts e.g. bis(dodecylphenyl)iodonium hexafluoroantimonate, octyloxyphenyl iodonium hexafluoroantimonate, phenyl iodonium hexafluoroantimonate, bisaryliodonium tetrakis(pentafluorophenyl)borate, triarylsulphonium salts, and combinations thereof. Preferably, the catalyst is a bisaryliodonium salt. Optionally, an effective amount of a free-radical generating compound can be added as the optional reagent such as aromatic pinacols, benzoinalkyl ethers, organic peroxides, and combinations thereof. The free radical generating compound facilitates decomposition of onium salt at lower temperature.

Optionally, an epoxy hardener such as carboxylic acid-anhydride curing agents and an organic compound containing hydroxyl moiety are present as optional reagents with the cure catalyst. In these cases, cure catalysts may be selected from typical epoxy curing catalysts that include, but are not limited to amines, alkyl-substituted imidazole, imidazolium salts, phosphines, metal salts, and combinations thereof. Suitable catalysts include, but are not limited to, triphenyl phosphine, alkyl-imidazole, aluminum acetyl acetonate, and combinations thereof.

Exemplary anhydride curing agents typically include methylhexahydrophthalic anhydride, 1,2-cyclohexanedicarboxylic anhydride, bicyclo[2.2.1]hept-5-ene-2,3-dicarboxylic anhydride, methylbicyclo[2.2.1]hept-5-ene-2,3-dicarboxylic anhydride, phthalic anhydride, pyromellitic dianhydride, hexahydrophthalic anhydride, dodecenylsuccinic anhydride, dichloromaleic anhydride, chlorendic anhydride, tetrachlorophthalic anhydride, and the like. Combinations comprising at least two anhydride curing agents may also be used. Illustrative examples are described in “Chemistry and Technology of the Epoxy Resins” B. Ellis (Ed.) Chapman Hall, New York, 1993 and in “Epoxy Resins Chemistry and Technology”, C. A. May (Ed.), Marcel Dekker, New York, 2nd edition, 1988.

Examples of organic compounds containing hydroxyl moiety include diols of the formula HO—W—OH, wherein W is a C₁-C₂₀ divalent aliphatic radical, a C₃-C₄₀ divalent cycloaliphatic radical, or a C₃-C₄₀ divalent aromatic radical. Aliphatic diols are illustrated by but are not limited to ethylene glycol; propylene glycol, i.e., 1,2- and 1,3-propylene glycol; 2,2-dimethyl-1,3-propane diol; 2-ethyl, 2-methyl, 1,3-propane diol; 1,3- and 1,5-pentane diol; dipropylene glycol; 2-methyl-1,5-pentane diol; and 1,6-hexane diol; triethylene glycol; 1,10-decane diol and mixtures thereof. Cycloaliphatic diols are illustrated by but are not limited to 1,1-decalindimethanol, 2,2-bicyclooctanedimethanol; cis-1,4-cyclohexanedimethanol; trans-1,4-cyclohexanedimethanol; and mixtures thereof. In one embodiment a mixture of diols comprising at least 2 diols selected from the group consisting of bisphenols, aliphatic diols, and cycloaliphatic diols is employed.

Examples of bisphenols include 1,1-bis(4-hydroxyphenyl)-3,3,5-trimethylcyclohexane; 2,2-bis(4-hydroxyphenyl)propane (commonly known as bisphenol A); 2,2-bis(4-hydroxy-3,5-dimethylphenyl)propane; 2,4′-dihydroxydiphenylmethane; bis(2-hydroxyphenyl)methane; bis(4-hydroxyphenyl)methane; bis(4-hydroxy-5-nitrophenyl)methane; bis(4-hydroxy-2,6-dimethyl-3-methoxyphenyl)methane; 1,1-bis(4-hydroxyphenyl)ethane; 1,1-bis(4-hydroxy-2-chlorophenyl)ethane; 2,2-bis(3-phenyl-4-hydroxyphenyl)propane; bis(4-hydroxyphenyl)cyclohexylmethane; 2,2-bis(4-hydroxyphenyl)-1-phenylpropane; 2,2,2′,2′-tetrahydro-3,3,3′,3′-tetramethyl-1,1′-spirobi[1H-indene]-6,6′-diol (commonly known as SBI); 2,2-bis(4-hydroxy-3-methylphenyl)propane (commonly known as DMBPC); resorcinol; and C₁-C₃ alkyl-substituted resorcinols. Most typically, 2,2-bis(4-hydroxyphenyl)propane (BPA) is used. Combinations of organic compounds containing hydroxyl moieties can also be used.

A reactive organic diluent may also be added to the total curable epoxy formulation to decrease the viscosity of the composition. Examples of reactive diluents include, but are not limited to, 3-ethyl-3-hydroxymethyl-oxetane, dodecylglycidyl ether, 4-vinyl-1-cyclohexane diepoxide, di(β-(3,4-epoxycyclohexyl)ethyl)-tetramethyldisiloxane, and combinations thereof. An unreactive diluent may also be added to the composition to decrease the viscosity of the formulation. Examples of unreactive diluents include, but are not limited to toluene, ethyl acetate, butyl acetate, 1-methoxy propyl acetate, ethylene glycol, dimethyl ether, and combinations thereof.

As noted, the curable flowable thermally conductive material may comprise at least one filler. Suitable fillers include, for example, fused silica, fumed silica, colloidal silica, boron nitride, aluminum nitride, silicon nitride, kaolin, quartz powder, carbon black, aluminum, alumina, copper, silver, gold, platinum, palladium, beryllium, boron, rhodium, nickel, cobalt, iron, molybdenum, tin, lead, chromium, zinc, magnesium, tungsten, bismuth, cadmium, gallium, indium, mercury, antimony, scandium, polonium, antimony oxide, iron oxide, zinc oxide, nickel oxide, silver oxide and combinations thereof. When present, the filler is typically present in a range between about 10 weight % and about 95 weight %, based on the total weight of the formulation. More typically, the filler is present in a range between about 20 weight % and about 85 weight %, based on the total weight of the curable polymer reinforcement material.

The curable flowable thermally conductive material may further comprise a flexibilizer component. Flexibilizers are used to increase the flexibility of the cured material. This is chosen so that there is more room for greater stress relief in the final device to prevent any failures such as cracking. An exemplary flexibilizer is the product D.E.R 732 that is available from Dow Chemical Co., Midland, Mich.

The curable flowable thermally conductive material may further comprise adhesion promoters such as trialkoxyorganosilanes e.g. omega-aminopropyltrimethoxysilane, 3-glycidoxypropyltrimethoxysilane, bis(trimethoxysilylpropyl)fumarate, and combinations thereof used in an effective amount which is typically in a range between about 0.01% by weight and about 2% by the total weight of the curable polymer reinforcement material.

Flame retardants may optionally be used in a range between about 0.5 weight % and about 20 weight % relative to the total weight of the polymer reinforcement material. Examples of flame retardants include phosphoramides, triphenyl phosphate (TPP), resorcinol diphosphate (RDP), bisphenol-A-disphosphate (BPA-DP), organic phosphine oxides, halogenated epoxy resin, metal oxide, metal hydroxides, and combinations thereof.

The curable flowable thermally conductive material may be prepared by hand mixing the components but also can be prepared using standard mixing equipment such as dough mixers, chain can mixers, planetary mixers, twin screw extruders, roll mills and the like. The blending can be performed in batch, continuous, or semi-continuous mode.

In one embodiment of the present invention the curable flowable thermally conductive material is a liquid that having a viscosity of from about 20 centipoise to about 5000 centipoise at ambient temperature. In another embodiment of the present invention the curable flowable thermally conductive material is a liquid that having a viscosity of from about 25 centipoise to about 3000 centipoise at ambient temperature. In yet another embodiment of the present invention the curable flowable thermally conductive material is a liquid that having a viscosity of from about 50 centipoise to about 1000 centipoise at ambient temperature.

The coating of any desired surface with the curable flowable thermally conductive material may be achieved by any of the methods known to those of ordinary skill in the art. Such methods include, but are not limited to dispensing, printing, screen printing, and combinations thereof. Patterns may also be formed on the surface as desired by the techniques described. In one embodiment, the curable flowable thermally conductive material is applied to a surface and subsequently is partially cured (“B-staged”). Partial curing of solvent-free curable flowable thermally conductive materials is, in one embodiment, effected by heating (thermal curing). Solvent-free curable flowable thermally conductive materials may be advantageous in that typically the curing of such materials while requiring a thermal upgrading cycle does not require the assistance of a vacuum environment. Other typical curing methods include vacuum evaporation, radiation curing, UV light curing, microwave curing, combinations thereof, and the like. A method of partially curing (“B-staging”) the curable flowable thermally conductive material is heating to a temperature in the range from about 10° C. to about 250° C., more typically in a range of from about 20° C. to about 225° C., under vacuum in a range from about 760 Torr to about 1 millitorr, more typically in a range from about 200 Torr to 1 Torr. In addition, partial curing (B-staging) may typically occur over a time period in a range between about 30 seconds and about 5 hours, and more typically in a range between about 90 seconds and about 30 minutes. B-staging (partial curing) typically results in a “B-staged” curable flowable thermally conductive material which is more resistant to flow relative to the same material prior to B-staging. Depending on the particular material, B-staging may result in a hardening of the curable flowable thermally conductive material or simply an increase in the viscosity thereof.

In one embodiment of the present invention, a portion of the heat dissipating element is coated with a curable flowable thermally conductive material in an amount sufficient such that when the coated heat dissipating element is joined to the substrate linked to a semiconductor chip via at least one electrical interconnect an electrical structure is formed in which the curable flowable thermally conductive material completely encapsulates the semiconductor chip. As noted, an electrical structure is formed when a heat dissipating element or an assembly comprising a heat dissipating element is joined to the assembly comprising the substrate, the semiconductor chip, at least one electrical interconnect, and an interlayer zone.

In another embodiment, the curable flowable thermally conductive material is used to fill the interlayer zone (i.e. is applied as an underfill), and subsequently, the same curable flowable thermally conductive material is coated onto the exposed side of the semiconductor chip.

Curing of the curable flowable thermally conductive material may be conducted with or without an independent and B-staging step. Typically, during curing the complete assembly (i.e. the electrical structure) is subjected to at least one curing step. Typical curing methods include thermal curing, UV light curing, radiation curing, microwave curing, combinations thereof, and the like. In one embodiment, suitable curing conditions comprise heating at a temperature in a range of from about 10° C. to about 250° C., in an alternate embodiment in a range of from about 20° C. to about 225° C. Heating can be carried out under vacuum, for example in a range from about 760 Torr to about 1 millitorr. In one embodiment curing is effected by heating under vacuum in a range from about 200 Torr to 1 Torr. In one embodiment curing is effected over a time period ranging between about 30 seconds and about 5 hours. In certain embodiments curing times range between about 90 seconds and about 30 minutes.

In one embodiment, the electronic device provided by the present invention comprises a cured thermally conductive material, a substrate that is linked to a semiconductor chip via at least one electrical interconnect, an interlayer zone defined by the substrate, the semiconductor chip and the at least one electrical interconnect, and a heat dissipating element disposed on the opposite face of the semiconductor chip from the substrate. The heat dissipating element is in contact with the semiconductor chip through the cured thermally conductive material. In one embodiment, the cured thermally conductive material encapsulates the semiconductor chip fully, and also fills the interlayer zone completely. Thus, the cured thermally conductive material serves as both a thermal interface material and as an underfill material. In an alternate embodiment, the cured thermally conductive material encapsulates the semiconductor chip fully, but only fills the interlayer zone incompletely.

In another embodiment of the invention, the electronic device comprises a cured thermally conductive material, a substrate linked to a WLCSP via at least one electrical interconnect, an interlayer zone defined by the substrate, the WLCSP and the electrical interconnect, and a heat dissipating element disposed on the opposite face of the WLCSP from the substrate. The heat dissipating element is in contact with the WLCSP through the cured thermally conductive material. In one embodiment, the thermally conductive material encapsulates the WLCSP fully, and partially fills the interlayer zone. In an alternate embodiment, the thermally conductive material only partially encapsulates the WLCSP, and the interlayer zone is either completely filled or is only partially filled.

The thickness of the interlayer zone in the electronic device obtained after the curing step is called the gap height. The gap height may depend upon factors such as the geometry of the substrate pad, the dimensions of the electrical interconnect, the composition of a solder ball, solder mask dimensions, assembly parameters, and curing conditions.

The thickness of the region between the heat dissipating element and the semiconductor chip (or WLCSP) is called the Bond-Line Thickness (“BLT”). The BLT may also be controlled by varying the composition of the curable flowable thermally conductive material.

### EXAMPLES

Aluminum was obtained from Atlantic Equipment Engineers, Bergenfield, N.J. Alumina was obtained from Denka Corp., New York, N.Y. Epoxy Cresol Novolac (ECN) was obtained from Sumitomo Chemical Co. Ltd., Tokyo, Japan. Bisphenol-A based diepoxide under the trade name Epon 826 was obtained from Resolution Performance Products, Pueblo, Colo. Tamanol was obtained from Schenectady International, Schenectady, N.Y. 1-Methoxy-2-propanol and N-methylimidazole were obtained from Sigma-Aldrich, USA.

Flip-Chip Assembly

A flip-chip device was assembled onto a high glass transition temperature (Tg) glass-reinforced FR-4 substrate. The flip-chip was a silicon device with standard eutectic tin-lead (63Sn/37Pb) solder bumps 4 milli-inches in height and a melting point of 183° C. The flip-chip device had 88 Input/Output (I/Os) and a pitch of 8 milli-inches. The passivation layer on the device was silicon nitride. The flip-chip dies were daisy chained to facilitate resistance monitoring and failures during reliability testing. The flip-chip was assembled onto copper pads on the substrate using a no-clean tacky flux and a tin-lead solder reflow profile. Solder interconnections that were 2 milli-inches in height were formed between the silicon device and the substrate.

Application of the Curable Flowable Thermally Conductive Material

20 milligrams of the curable flowable thermally conductive material was dispensed onto copper with matte nickel finish heat dissipating element in a half dispense pattern. The material was then B-staged. The B-staged material retained the shape in which it was dispensed.

Electronic Device Fabrication

The heat dissipating element with the B-staged material was placed onto the backside of the flip chip assembly and a metallic clip that exerted 1 pound of force was applied to hold the heat dissipating element and the flip chip assembly together. The entire assembly with the heat spreader and clip was placed in an isothermal oven at 150° C. for forty minutes. The B-staged material flowed under these curing conditions, filling the space between the heat dissipating element (heat spreader) and the flip chip backside. The B-staged material also flowed down along the edge of the flip chip device and under the flip chip device to form a cured underfill layer.

Characterization of Devices

Thermal Resistance Measurement Sample Preparation

The material was B-staged and assembled between 8 millimeter×8 millimeter coupons of silicon and copper. The assembly was subjected to suitable curing conditions to obtain a cured sample. The thickness of each coupon was measured at five different locations, before the assembly step. The thickness of the coupons was subtracted from the cured assembled device thickness to obtain the Bondline Thickness (BLT) of the layer. This assembly was then coated with a thin layer of graphite before placing them in a laser flash diffusivity instrument.

Thermal Diffusivity Instrument and Measurement of Thermal Resistance

A laser flash instrument (Netzsch Instruments, Microflash 300), whose operation is based on the principle described in ASTM E-1461 and in “Measurements of Adhesive Bondline Effective Thermal Conductivity and Thermal Resistance Using the Laser Flash Method”, Campbell, Robert C, Smith, Stephen E. and Dietz, Raymond L., 15^{th} IEEE Semi-Therm Symposium, 1999, 83-97, was used for the measurement of in-situ thermal diffusivity and thermal conductivities. Temperature was maintained at 25° C. A software macro that was provided with the Microflash™ instrument was used to determine the thermal conductivity and thermal resistance of the cured material layer. The thermal resistance of the cured material layer that was determined using this method includes the bulk (intrinsic) thermal resistance of the cured material and the contact resistances at the material-substrate interfaces. This thermal resistance value best represents the in-situ performance of the cured materials.

Adhesion Strength Measurement

The adhesive property of the cured material was characterized using a die shear test, which was performed utilizing a Dage model 22 microtester with a 20 kilogram load cell. The curable flowable thermally conductive material was B-staged onto 4 millimeter×4 millimeter semiconductor chip and then assembled and cured onto solder mask covered FR-4 substrates. Gripping fixtures held the substrate in place. The movement of the shear anvil on the Dage microtester was tightly controlled in the x, y, and z directions. The shear anvil was positioned against the edge of the die with the help of a microscope, and a uniform force was applied until the die either fractured or separated from the substrate/coupon. The load that was required to shear the semiconductor chip off the substrate divided by the shear area yielded the die shear strength.

Reliability Performance Testing

An accelerated reliability test was used to evaluate the performance of the test systems. In the air-to-air thermal shock test, samples were subjected to temperature extremes of 0° C. and 100° C. or −50 and 150° C. (10 minutes per cycle). The thermal resistance of the cured thermally conductive layer before and after reliability testing was monitored. The resistance of the flip chip solder joints was also monitored with reliability cycling using the daisy chained flip chip die.

Table 1 gives the compositions of the curable flowable thermally conductive material used in the method for forming electronic devices. Table 2 gives the results of the characterization of the devices for its performance.

TABLE 1
Compositions of Curable Flowable Thermally Conductive Material

| | Weight % Component | | | | |
|---|---|---|---|---|---|
| Sample | Epoxy Cresol | EPON | | 1-Methoxy- | |
| # | Novolac | 826 | Tamanol | 2-Propanol | Filler |
| 1 | 33.97 | 28.03 | 19.57 | 18.43 | None |
| 2 | 10.19 | 8.41 | 5.87 | 5.53 | Aluminum |
| | | | | | 70% |
| 3 | 10.19 | 8.41 | 5.87 | 5.53 | Alumina |
| | | | | | 70% |

TABLE 2
Results of the measurements of different parameters of the
Flip Chip Assembly that were prepared using various curable
flowable thermally conductive material compositions

| | | | | | Thermal | Solder |
|---|---|---|---|---|---|---|
| | | | | | Perfor- | Joint |
| Sam- | | Adhesive | CTE, | | mance, | Reliability, |
| ple | BLT, | Strength, | ppm/ | Tg, | mm² | cycles to |
| # | μm | psi | C | ° C. | K/W | failure |
| Con- | — | — | — | — | — | 250^{2,3} |
| trol¹ | | | | | | |
| 1 | 18 ± 2.9 | 5400 ± 2200 | 60 | 163 | 85 | >250³ |
| 2 | 22.3 ± 1 | 7900 ± 950 | 51 | 128 | 25 | 750² |
| 3 | 47 ± 4.5 | 6850 ± 1850 | 38 | 107 | 56 | 750² |

¹Control Sample is an assembly that does not comprise any underfill or a thermal interface material.
²Testing done at a temperature range of from about 0° C. to about 100° C.
³Testing done at a temperature range of from about −50° C. to about 150° C.

Results given in table 2 illustrate the effectiveness of the method of the present invention in providing electrical structures capable of use in electronic devices, as evidenced by the robust solder joint reliability of the tested flip-chip assemblies.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A method of forming an electronic device, said method comprising the steps of:
(A) providing a substrate linked to a semiconductor chip via at least one electrical interconnect, said substrate and said semiconductor chip and said at least one electrical interconnect defining an interlayer zone;
(B) coating a predetermined portion of a heat dissipating element with a curable flowable thermally conductive material to provide a coated heat dissipating element;
(C) joining the coated heat dissipating element with the semiconductor chip to provide an electrical structure comprising a heat dissipating element, a substrate linked to a semiconductor chip via at least one electrical interconnect; said electrical structure comprising an interlayer zone defined by the substrate, the electrical interconnect, and the semiconductor chip; and causing the curable flowable thermally conductive material to fill at least a portion of said interlayer zone and subsequently curing the curable flowable thermally conductive material.

2. The method according to claim 1, further comprising a step of B-staging the curable flowable thermally conductive material.

3. The method according to claim 2, wherein the step of B-staging comprises heating to a temperature in the range of from about 50° C. to about 250° C.

4. The method according to claim 2, wherein the step of B-staging comprises applying vacuum in the range of from about 25 Torr to about 250 Torr.

5. The method according to claim 1, wherein the curable flowable thermally conductive material comprises a filler selected from the group consisting of fused silica, fumed silica, colloidal silica, aluminum, alumina, boron nitride, aluminum nitride, silicon nitride, kaolin, quartz powder, carbon black, aluminum, alumina, copper, silver, gold, platinum, palladium, boron, beryllium, rhodium, nickel, cobalt, iron, molybdenum, tin, lead, chromium, zinc, magnesium, tungsten, bismuth, cadmium, gallium, indium, mercury, antimony, scandium, polonium, antimony oxide, iron oxide, zinc oxide, nickel oxide, silver oxide and combinations thereof.

6. The method according to claim 1, wherein the curable flowable thermally conductive material comprises an epoxy resin.

7. The method according to claim 1, wherein said curing step comprises heating to a temperature in the range of from about 50° C. to about 250° C.

8. An electronic device made by the method of claim 1.

9. An electronic device comprising:
(A) a substrate;
(B) a semiconductor chip that is linked to the substrate via at least one electrical interconnect, said substrate and said semiconductor chip and said at least one electrical interconnect defining an interlayer zone;
(C) a heat dissipating element; and
(D) a cured thermally conductive material that forms a thermal interface layer between the heat dissipating element and the semiconductor chip, said cured thermally conductive material also occupying at least a portion of said interlayer zone,
said electronic device being substantially free of sealant material other than the cured thermally conductive material joining the heat dissipating element to the substrate.

10. The electronic device structure of claim 9, wherein the thermally conductive material is also a reinforcement material.

11. The electronic device structure of claim 9, wherein the thermally conductive material is a B-staged material.

12. The electronic device structure of claim 9, wherein the thermally conductive material is fully cured.

13. The electronic device structure of claim 9, wherein the thermally conductive material is derived from an epoxy compound.

14. A method of forming an electronic device, said method comprising the steps of:
(A) providing a substrate linked to a semiconductor chip via at least one electrical interconnect, said substrate and said semiconductor chip and said at least one electrical interconnect defining an interlayer zone;
(B) filling at least a portion of said interlayer zone with a curable flowable thermally conductive material;
(C) coating a predetermined portion of the semiconductor chip;
(D) joining a structure formed by steps (A)-(C) to a heat dissipating element; and
(E) curing the curable flowable thermally conductive material,
said electronic device being substantially free of sealant material other than the cured thermally conductive material joining the heat dissipating element to the substrate.

15. The method according to claim 14, further comprising a step of B-staging the curable flowable thermally conductive material.

16. The method according to claim 15, wherein the B-staging step comprises heating to a temperature in the range of from about 50° C. to about 250° C.

17. The method according to claim 15, wherein the B-staging step comprises applying vacuum in the range of from about 25 Torr to about 250 Torr.

18. The method according to claim 14, wherein the curable flowable thermally conductive material comprises a filler selected from the group consisting of fused silica, fumed silica, colloidal silica, aluminum, alumina, boron nitride, aluminum nitride, silicon nitride, kaolin, quartz powder, carbon black, aluminum, alumina, copper, silver, gold, platinum, palladium, boron, beryllium, rhodium, nickel, cobalt, iron, molybdenum, tin, lead, chromium, zinc, magnesium, tungsten, bismuth, cadmium, gallium, indium, mercury, antimony, scandium, polonium, antimony oxide, iron oxide, zinc oxide, nickel oxide, silver oxide and combinations thereof.

19. The method according to claim 14, wherein the curable flowable thermally conductive material comprises an epoxy resin.

20. The method according to claim 14, wherein said curing step comprises heating to a temperature in the range of from about 50° C. to about 250° C.

21. A system comprising at least one electronic device, said electronic device being prepared by a method, said method comprising
(A) providing a substrate linked to a semiconductor chip via at least one electrical interconnect, said substrate and said semiconductor chip and said at least one electrical interconnect defining an interlayer zone;
(B) coating a predetermined portion of a heat dissipating element with a curable flowable thermally conductive material to provide a coated heat dissipating element;
(C) joining the coated heat dissipating element with the semiconductor chip to provide an electrical structure comprising a heat dissipating element, a substrate linked to a semiconductor chip via at least one electrical interconnect; said electrical structure comprising an interlayer zone defined by the substrate, the electrical interconnect, and the semiconductor chip; and causing the curable flowable thermally conductive material to fill at least a portion of said interlayer zone and subsequently curing the curable flowable thermally conductive material.

22. A system comprising at least one electronic device, said electronic device comprising
(A) a substrate;
(B) a semiconductor chip that is linked to the substrate via at least one electrical interconnect, said substrate and said semiconductor chip and said at least one electrical interconnect defining an interlayer zone;
(C) a heat dissipating element; and
(D) a cured thermally conductive material that forms a thermal interface layer between the heat dissipating element and the semiconductor chip, said cured thermally conductive material also occupying at least a portion of said interlayer zone,
said electronic device being substantially free of sealant material other than the cured thermally conductive material joining the heat dissipating element to the substrate.

23. A system comprising at least one electronic device, said electronic device being prepared by a method, said method comprising
(A) providing a substrate linked to a semiconductor chip via at least one electrical interconnect, said substrate and said semiconductor chip and said at least one electrical interconnect defining an interlayer zone;
(B) filling at least a portion of said interlayer zone with a curable flowable thermally conductive material;
(C) coating a predetermined portion of the semiconductor chip;
(D) joining a structure formed by steps (A)-(C) to a heat dissipating element; and
(E) curing the curable flowable thermally conductive material,
said electronic device being substantially free of sealant material other than the cured thermally conductive material joining the heat dissipating element to the substrate.
